(19) United States
(12) Patent Application Publication
(10) Pub. No.: US 2018/0183360 A1
(43) Pub. Date: Jun. 28, 2018

(54) THERMOELECTRIC CONVERSION MODULE

(71) Applicant: FUJIFILM Corporation, Tokyo (JP)

(72) Inventors: Hideyuki SUZUKI, Kanagawa (JP); Shinji IMAI, Kanagawa (JP)

(73) Assignee: FUJIFILM Corporation, Tokyo (JP)

(21) Appl. No.: 15/903,086

(22) Filed: Feb. 23, 2018

Related U.S. Application Data
(63) Continuation of application No. PCT/JP2016/075077, filed on Aug. 26, 2016.

(30) Foreign Application Priority Data
Aug. 31, 2015 (JP) 2015-170816
May 31, 2016 (JP) 2016-108743

(51) Int. Cl. H02N 11/00; H01L 23/48; H01L 23/14; H01L 23/52

(52) U.S. Cl. CPC H02N 11/002; H01L 23/52; H01L 23/14; H01L 23/48

(57) ABSTRACT

The present invention addresses the problem of providing a thermoelectric conversion module which suppresses a decrease in a power generation amount and exhibits high power output. The thermoelectric conversion module includes a thermoelectric conversion module substrate in which a P-type thermoelectric conversion element having a P-type thermoelectric conversion layer and a pair of connection electrodes, which are electrically connected to the P-type thermoelectric conversion layer, is provided on at least one surface of an insulating substrate, and an N-type thermoelectric conversion element having an N-type thermoelectric conversion layer and a pair of connection electrodes, which are electrically connected to the N-type thermoelectric conversion layer, is provided at least the other surface of the insulating substrate. The connection electrodes formed on the one surface of the insulating substrate and the connection electrodes formed on the other surface of the insulating substrate opposite to the one surface are electrically connected to each other, or a plurality of the thermoelectric conversion module substrates are laminated by being connected to each other through the connection electrodes.

### CROSS-REFERENCE TO RELATED APPLICATIONS

This application is a Continuation of PCT International Application No. PCT/JP2016/075077 filed on Aug. 26, 2016, which claims priority under 35 U.S.C. § 119(a) to Japanese Patent Application No. 2015-170816 filed on Aug. 31, 2015 and Japanese Patent Application No. 2016-108743 filed on May 31, 2016. Each of the above applications is hereby expressly incorporated by reference, in its entirety, into the present application.

### BACKGROUND OF THE INVENTION

### 1. Field of the Invention

The present invention relates to a thermoelectric conversion module in which thermoelectric conversion elements are provided on both surfaces of an insulating substrate, and particularly relates to a thermoelectric conversion module exhibiting high power generation output.

### 2. Description of the Related Art

Thermoelectric conversion materials that can mutually convert thermal energy and electric energy are used in power generating elements that generate power by a temperature difference, and in thermoelectric conversion elements such as Peltier elements.

In regard to such thermoelectric conversion elements, for example, among thermoelectric conversion elements in which a Bi-Te-based inorganic semiconductor is used as a thermoelectric conversion material, a π-type thermoelectric conversion element is known. A π-type thermoelectric conversion element is produced by processing a thermoelectric conversion material into blocks, arranging the blocks on an insulating substrate of ceramic or the like, and electrically connecting the blocks.

On the other hand, a thermoelectric conversion element obtained by forming a film of an ink-like thermoelectric conversion material on an insulating substrate in a coating step or a printing step is reported. This thermoelectric conversion element is easily manufactured and thus the manufacturing cost can be cheaper than the manufacturing cost for a π-type thermoelectric conversion element. In the thermoelectric conversion element having such a structure, power can be generated by causing a temperature difference on a two-dimensional plane of the insulating substrate and imparting a sufficient temperature difference to the thermoelectric conversion material. Regarding this point, for example, description is made in JP2012-212838A.

JP2004-253426A discloses a thermoelectric conversion device in which thermoelectric conversion elements are produced on both surfaces of an insulating material such as a sheet substrate or the like and the thermoelectric conversion elements on the both surfaces are electrically connected to each other by through-hole plating. According to JP2004-253426A, the volume of the insulating substrate in the thermoelectric conversion element can be reduced by adopting the above configuration. In JP2004-253426A, it is described that a short circuit between the thermoelectric conversion elements facing each other is prevented by arranging an insulating layer between the insulating materials to be overlapped.

JP2008-130813A discloses a thermal power generation device including an insulating sheet having flexibility and including a plurality of formation regions in which a thermocouple is formed and a plurality of non-formation regions in which a thermocouple is not formed, a plurality of thermocouples which are formed in each of the plurality of formation regions of the insulating sheet and connected to each other in series, and a connection pattern which is formed in the non-formation regions of the insulating sheet and connects the plurality of thermocouples respectively formed in each of the plurality of formation regions in series, in which the plurality of thermocouples include a plurality of p-type semiconductor patterns which are formed on a surface of the insulating sheet, a plurality of n-type semiconductor patterns which are formed on a rear surface of the insulating sheet, and a plurality of through-hole platings which penetrate through the insulating sheet to alternately connect to the p-type semiconductor pattern and the n-type semiconductor pattern. The insulating sheet disclosed in JP2008-130813A is fixed by a resin member in a state in which the insulating sheet is alternately mountain-folded and valley-folded in the plurality of non-formation regions.

### SUMMARY OF THE INVENTION

However, as described in JP2012-212838A, in the two-dimensional thermoelectric conversion element structure on the insulating substrate, the proportion of the insulating substrate in the thermoelectric conversion element is high and the insulating substrate transfers heat to cause a decrease in a power generation amount. In addition, due to a decrease in the manufacturing cost, the percentage of the cost of the insulating substrate in the entire cost of the thermoelectric conversion element is increased and thus a decrease in the usage amount of the insulating substrate directly contributes to a decrease in the cost of the thermoelectric conversion element.

In the thermoelectric conversion element, in order to increase the power generation amount, it is required that a plurality of insulating substrates in which the thermoelectric conversion elements are formed on both surfaces are overlapped and electrically connected to each other. As described in JP2004-253426A, in the insulating substrate in which the thermoelectric conversion elements are formed on both surfaces of the insulating material, in a case where the plurality of insulating materials are overlapped, the thermoelectric conversion elements facing each other come into contact with each other to cause a short circuit. As a result, the power generation amount is significantly decreased. Thus, in JP2004-253426A, a short circuit between the facing thermoelectric conversion elements is prevented by arranging the insulating layer between the insulating materials overlapped as described above. In a case where the insulating layer is arranged between the thermoelectric conversion elements as described above, the insulating layer functions as a heat conductive medium and thus there is a problem of decreasing a temperature difference between the thermoelectric conversion elements.

In addition, JP2008-130813A discloses the use in a state in which the plurality of formation regions in which facing thermocouples are formed do not come into contact with each other. However, compared to a state in which the insulating substrates are overlapped, the heat transfer area is significantly increased and thus there is a problem of decreasing power generation output density, that is, decreasing the power generation amount per unit heat transfer area.

An object of the present invention is to solve the above problems of the related art and to provide a thermoelectric conversion module which suppresses a decrease in the power generation amount and exhibits high power generation output.

In order to achieve the above object of the present invention, there is provided a thermoelectric conversion module comprising: a thermoelectric conversion module substrate in which a P-type thermoelectric conversion element having a P-type thermoelectric conversion layer and a pair of connection electrodes, which are electrically connected to the P-type thermoelectric conversion layer, is provided on at least one surface of an insulating substrate, and an N-type thermoelectric conversion element having an N-type thermoelectric conversion layer and a pair of connection electrodes, which are electrically connected to the N-type thermoelectric conversion layer, is provided on at least the other surface of the insulating substrate,

wherein the connection electrodes formed on the one surface of the insulating substrate and the connection electrodes formed on the other surface of the insulating substrate opposite to the one surface are electrically connected to each other, and

a plurality of the thermoelectric conversion module substrates are laminated such that the P-type thermoelectric conversion elements or the N-type thermoelectric conversion elements are made to face each other, and the respective laminated thermoelectric conversion module substrates are connected to each other through the connection electrodes.

It is preferable that the connection electrode formed on the one surface of the insulating substrate and the connection electrode formed on the other surface of the insulating substrate opposite to the one surface are electrically connected to each other by at least one through electrode formed on the insulating substrate.

It is preferable that the P-type thermoelectric conversion elements or the N-type thermoelectric conversion elements in the respective laminated thermoelectric conversion module substrates are electrically connected to each other in parallel through the connection electrodes.

It is preferable that the P-type thermoelectric conversion element and the N-type thermoelectric conversion element in the respective laminated thermoelectric conversion module substrates are electrically connected to each other through the connection electrodes.

It is preferable that only the P-type thermoelectric conversion element is provided on one surface of the insulating substrate and only the N-type thermoelectric conversion element is provided on the other surface of the insulating substrate.

It is preferable that the P-type thermoelectric conversion element and the N-type thermoelectric conversion element are electrically connected to each other in series on one surface of the insulating substrate, and the P-type thermoelectric conversion element and the N-type thermoelectric conversion element are electrically connected to each other in series on the other surface of the insulating substrate.

It is preferable that the P-type thermoelectric conversion elements or the N-type thermoelectric conversion elements in the respective laminated thermoelectric conversion module substrates are electrically connected to each other in parallel by upper electrodes provided on at least the connection electrodes.

It is preferable that the upper electrodes are provided so as to cover connection portions of the connection electrodes and the P-type thermoelectric conversion layer and connection portions of the connection electrodes and the N-type thermoelectric conversion layer.

It is preferable that the upper electrodes are separately provided on one connection electrode side of the pair of connection electrodes and the other connection electrode side.

For example, the insulating substrate is formed of a polyimide. For example, the connection electrode is formed of copper. For example, the through electrode is formed of copper.

It is preferable that the P-type thermoelectric conversion layer and the N-type thermoelectric conversion layer are formed of an organic thermoelectric conversion material.

It is preferable that the P-type thermoelectric conversion layer and the N-type thermoelectric conversion layer contain a carbon nanotube. It is preferable that the upper electrode is formed of solder.

According to a second invention, there is provided a thermoelectric conversion module comprising: a P-type thermoelectric conversion module substrate in which a P-type thermoelectric conversion element having a P-type thermoelectric conversion layer and a pair of connection electrodes, which are electrically connected to the P-type thermoelectric conversion layer, is provided on one surface of an insulating substrate; and an N-type thermoelectric conversion module substrate in which an N-type thermoelectric conversion element having an N-type thermoelectric conversion layer and a pair of connection electrodes, which are electrically connected to the N-type thermoelectric conversion layer, is provided on one surface of the insulating substrate,

in which a P-type laminate formed by laminating two sheets of the P-type thermoelectric conversion module substrate such that the P-type thermoelectric conversion elements are arranged to face each other and an N-type laminate formed by laminating two sheets of the N-type thermoelectric conversion module substrate such that the N-type thermoelectric conversion elements are arranged to face each other are alternately laminated and in the laminated P-type laminate and N-type laminate, the P-type thermoelectric conversion element of the P-type thermoelectric conversion module substrate and the N-type thermoelectric conversion element of the N-type thermoelectric conversion module substrate are electrically connected to each other through the connection electrodes.

According to the present invention, it is possible to obtain a thermoelectric conversion module which exhibits high power generation output.

### BRIEF DESCRIPTION OF THE DRAWINGS

FIG. 1A is a schematic view showing a thermoelectric conversion device having a thermoelectric conversion module according to an embodiment of the present invention, and

FIG. 1B is a schematic view showing an equivalent circuit of the thermoelectric conversion module according to the embodiment of the present invention.

FIG. 2A is a schematic view showing a surface of a thermoelectric conversion module substrate of the thermoelectric conversion module according to the embodiment of the present invention, FIG. 2B is a schematic view showing a rear surface of FIG. 2A, FIG. 2C is a schematic view showing a surface of the thermoelectric conversion module substrate of the thermoelectric conversion module according to the embodiment of the present invention, FIG. 2D is a schematic view showing a rear surface of FIG. 2C, FIG. 2E is a schematic view showing a surface of the thermoelectric conversion module substrate of the thermoelectric conversion module according to the embodiment of the present invention, and FIG. 2F is a schematic view showing a rear surface of FIG. 2E.

FIG. 3A is a schematic view showing a first modification example of the thermoelectric conversion module according to the embodiment of the present invention, and FIG. 3B is a schematic view showing a second modification example of the thermoelectric conversion module according to the embodiment of the present invention.

FIGS. 4A to 4R are schematic views showing a step order of a method of manufacturing a connection electrode of the thermoelectric conversion module according to the embodiment of the present invention.

FIGS. 5A to 5L are schematic views showing a step order of a method of manufacturing the thermoelectric conversion module according to the embodiment of the present invention.

(a) of FIG. 6 is a schematic view showing a surface of a first thermoelectric conversion module substrate of another thermoelectric conversion module according to the embodiment of the present invention, (b) of FIG. 6 is a schematic view showing a rear surface of the first thermoelectric conversion module substrate of another thermoelectric conversion module according to the embodiment of the present invention, (c) of FIG. 6 is a schematic view showing a surface of a second thermoelectric conversion module substrate of another thermoelectric conversion module according to the embodiment of the present invention, (d) of FIG. 6 is a schematic view showing a rear surface of the second thermoelectric conversion module substrate of another thermoelectric conversion module according to the embodiment of the present invention, (e) of FIG. 6 is a schematic view showing a surface of a third thermoelectric conversion module substrate of another thermoelectric conversion module according to the embodiment of the present invention, and (f) of FIG. 6 is a schematic view showing a rear surface of the third thermoelectric conversion module substrate of another thermoelectric conversion module according to the embodiment of the present invention.

FIG. 7A is a schematic cross-sectional view showing a first cross section of another thermoelectric conversion module according to the embodiment of the present invention, FIG. 7B is a schematic cross-sectional view showing a second cross section of another thermoelectric conversion module according to the embodiment of the present invention, and FIG. 7C is a schematic cross-sectional view showing a third cross section of another thermoelectric conversion module according to the embodiment of the present invention.

FIG. 8 is a schematic view showing another example of the thermoelectric conversion module according to the embodiment of the present invention.

FIG. 9 is a schematic view showing a thermoelectric conversion module according to an embodiment of a second invention.

### DESCRIPTION OF THE PREFERRED EMBODIMENTS

Hereinafter, a thermoelectric conversion module of the present invention will be described in detail based on preferable embodiments shown in the accompanying drawings.

In the following description, “to” indicating a numerical value range includes numerical values described on both sides. For example, when ε is a numerical value α to a numerical value β, the range of ε is a range including the numerical value α and the numerical value β, and is represented as α≤ε≤β using mathematical symbols.

Unless otherwise specified, an angle means that a difference from the exact angle falls within a range of less than 5°. The difference from the exact angle is preferably less than 4° and more preferably less than 3°.

The meaning of “the same” includes an error range that is generally allowable in the technical field. In addition, the meaning of “entire surface” and the like includes not only 100% but also a case where an error range is generally allowable in the technical field, for example, 99% or more, 95% or more, or 90% or more.

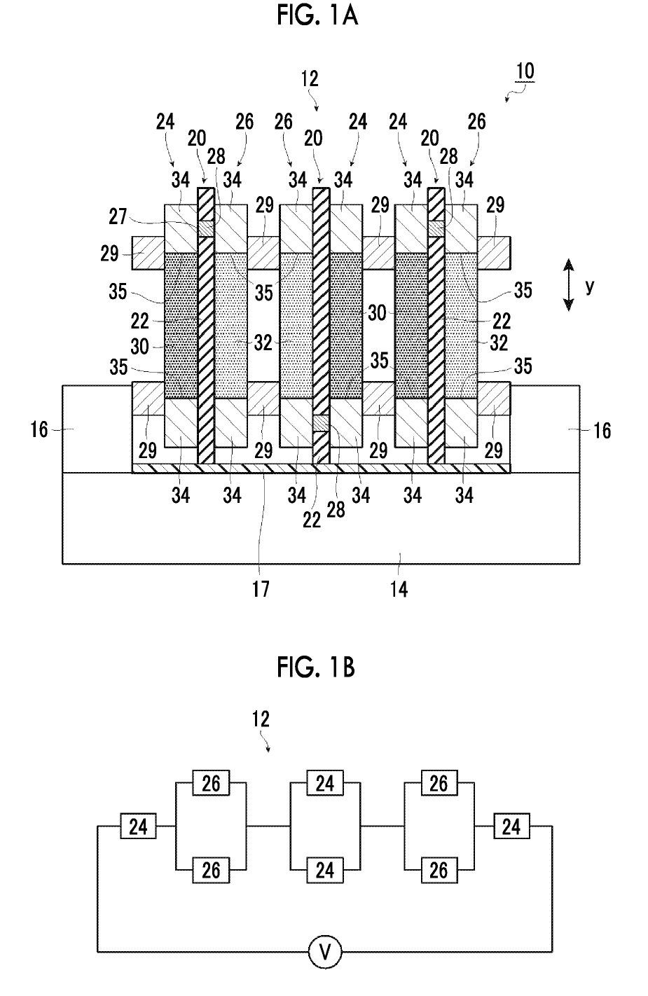

FIG. 1A is a schematic view showing a thermoelectric conversion device having a thermoelectric conversion module according to an embodiment of the present invention, and FIG. 1B is a schematic view showing an equivalent circuit of the thermoelectric conversion module according to the embodiment of the present invention.

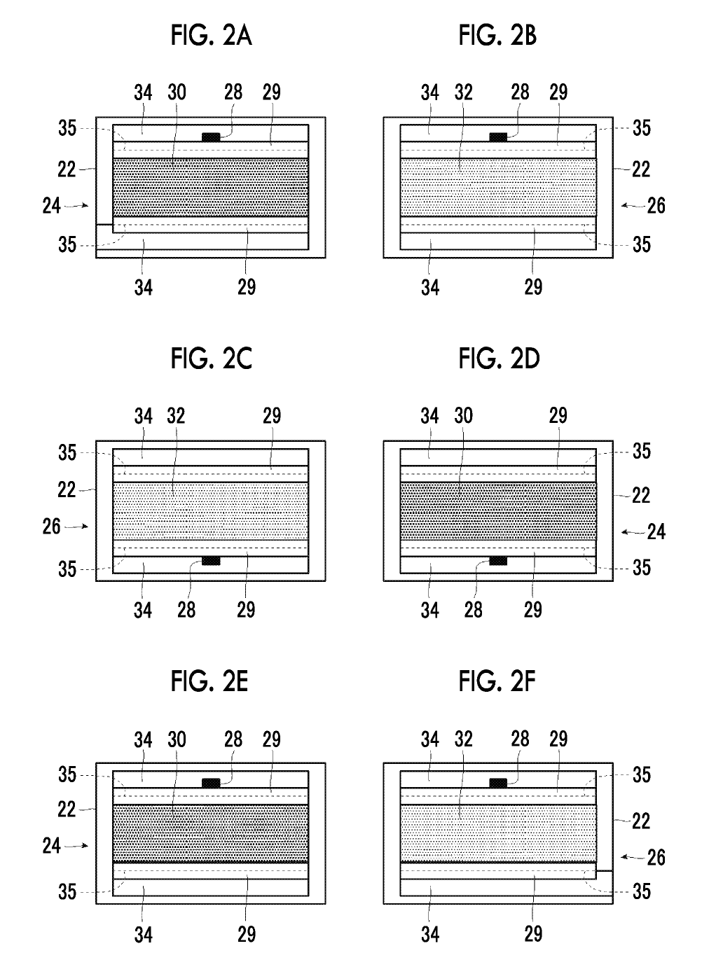

FIG. 2A is a schematic view showing a surface of a thermoelectric conversion module substrate of the thermoelectric conversion module according to the embodiment of the present invention, FIG. 2B is a schematic view showing a rear surface of FIG. 2A, FIG. 2C is a schematic view showing a surface of the thermoelectric conversion module substrate of the thermoelectric conversion module according to the embodiment of the present invention, FIG. 2D is a schematic view showing a rear surface of FIG. 2C, FIG. 2E is a schematic view showing a surface of the thermoelectric conversion module substrate of the thermoelectric conversion module according to the embodiment of the present invention, and FIG. 2F is a schematic view showing a rear surface of FIG. 2E. In FIGS. 2A to 2F, FIGS. 2A and 2B form a set, FIGS. 2C and 2D form a set, and FIGS. 2E and 2F form a set.

A thermoelectric conversion device 10 shown in FIG. 1A generates power by a thermoelectric conversion module 12 by using a temperature difference. The thermoelectric conversion device 10 has the thermoelectric conversion module 12, a base 14, and a frame 16.

On the base 14, the thermoelectric conversion module 12 is placed. For example, a thermally conductive sheet 17 is provided between the base 14 and the thermoelectric conversion module 12. The frame 16 is provided for fixing the thermoelectric conversion module 12 on the base 14 and the thermoelectric conversion module 12 is fitted in the frame to be fixed in FIG. 1A.

The base 14 is formed of, for example, a material having high thermal conductivity, such as a metal or an alloy. For example, the temperature of the base 14 is set to a relatively high temperature such that a temperature difference is generated in the thermoelectric conversion module 12 in a y direction in FIG. 1A, and thus power is generated in the thermoelectric conversion module 12 to obtain power generation output.

Since a current flows in an upper electrode 29 of the thermoelectric conversion module 12, a connection portion of the frame 16 and the upper electrode 29 is electrically insulated. The frame 16 is formed of a metal, an alloy, or the like.

The thermally conductive sheet 17 is provided for promoting thermal conduction from the base 14 to the thermoelectric conversion module 12. Specific examples of the thermally conductive sheet 17 will be described later.

The thermoelectric conversion module 12 is arranged on the base 14 in FIG. 1 A but there is no limitation thereto. For example, the thermoelectric conversion module may be arranged on a curved surface such as a surface of a cylinder.

In the thermoelectric conversion module 12, a plurality of thermoelectric conversion module substrates, in the example of FIG. 1A, three thermoelectric conversion module substrates 20, are laminated. Although described in detail later, each thermoelectric conversion module substrate 20 is electrically connected to the upper electrode 29.

In the thermoelectric conversion module of the present invention, the number of laminated thermoelectric conversion module substrates is not limited to 3 as shown in the drawing (the number of substrates shown in the drawing) and four or more (more than the number of substrates shown in the drawing) thermoelectric conversion module substrates may be laminated. Regarding this point, the same is applied to another thermoelectric conversion module.

As shown in FIGS. 1A and 2A to 2F, the thermoelectric conversion module substrate 20 has an insulating substrate 22 having electrically insulating properties, a P-type thermoelectric conversion element 24 provided on one surface of the insulating substrate 22, and an N-type thermoelectric conversion element 26 provided on the other surface of the insulating substrate 22 opposite to the one surface.

As shown in FIGS. 2A to 2F, in the thermoelectric conversion module substrate 20, the surface on which P-type thermoelectric conversion element 24 and the N-type thermoelectric conversion element 26 are provided varies depending on the arrangement position.

The P-type thermoelectric conversion element 24 has a P-type thermoelectric conversion layer 30 and a pair of connection electrodes 34. The connection electrodes 34 are electrically connected to both sides of the P-type thermoelectric conversion layer 30.

The N-type thermoelectric conversion element 26 has an N-type thermoelectric conversion layer 32 and a pair of connection electrodes 34. The connection electrodes 34 are connected to both sides of the N-type thermoelectric conversion layer 32.

The connection electrode 34 formed on one surface of the insulating substrate 22, that is, the connection electrode 34 of the P-type thermoelectric conversion element 24 and the connection electrode 34 formed on the other surface of the insulating substrate 22, that is, the connection electrode 34 of the N-type thermoelectric conversion element 26, are connected to a through electrode 28 formed on the insulating substrate 22.

The through electrode 28 is formed in a through hole 27 passing through the connection electrodes 34 and the insulating substrate 22. The number of through electrodes 28 is not particularly limited as long as electrical connection between the connection electrodes 34 can be secured. The number of through electrodes may be at least 1. In order to secure stability of electrical connection between the connection electrodes 34, a plurality of through electrodes 28 may be provided.

A plurality of thermoelectric conversion module substrates 20, in FIG. 1A, three thermoelectric conversion module substrates 20, are laminated such that the P-type thermoelectric conversion elements 24 or the N-type thermoelectric conversion elements 26 are made to face each other.

In the P-type thermoelectric conversion element 24, the upper electrodes 29 are provided on the connection electrodes 34 so as to cover connection portions 35 of the connection electrodes 34 and the P-type thermoelectric conversion layer 30 over the connection electrodes 34 and the P-type thermoelectric conversion layer 30. The upper electrodes 29 are respectively provided with respect to the connection electrodes 34 on both sides of the P-type thermoelectric conversion layer 30. The upper electrodes 29 are provided to be separated from each other in the P-type thermoelectric conversion element 24.

In the N-type thermoelectric conversion element 26, as in the P-type thermoelectric conversion element 24, the upper electrodes 29 are provided. In the N-type thermoelectric conversion element 26, the upper electrodes 29 are provided on the connection electrodes 34 so as to cover the connection portions 35 of the connection electrodes 34 and the N-type thermoelectric conversion layer 32 over the connection electrodes 34 and the N-type thermoelectric conversion layer 32. The upper electrodes 29 are respectively provided with respect to the connection electrodes 34 on both sides of the N-type thermoelectric conversion layer 32. The upper electrodes 29 are provided to be separated from each other in the N-type thermoelectric conversion element 26.

As described above, in a case where the upper electrodes 29 are provided to be separated from each other with respect to the P-type thermoelectric conversion element 24 and the N-type thermoelectric conversion element 26, a current preferentially flows in the P-type thermoelectric conversion layer 30 and the N-type thermoelectric conversion layer 32 and thus this case is preferable.

In the laminated thermoelectric conversion module substrates 20, the facing P-type thermoelectric conversion elements 24 are electrically connected to each other in parallel by the above-described upper electrode 29. The N-type thermoelectric conversion elements 26 are also electrically connected in parallel by the upper electrode 29. In the thermoelectric conversion module substrates 20 laminated this manner, the thermoelectric conversion elements having the same polarity are electrically connected to each other in parallel by the upper electrode 29.

In a case where a connection state of the P-type thermoelectric conversion elements 24 and the N-type thermoelectric conversion elements 26 of the thermoelectric conversion module 12 is schematically shown, the connection state is as shown in FIG. 1B. Other than the P-type thermoelectric conversion element 24 and the N-type thermoelectric conversion element 26 at both ends of the thermoelectric conversion module 12, the P-type thermoelectric conversion elements 24 and the N-type thermoelectric conversion elements 26 are electrically connected to each other in parallel.

Regarding the positions at which the through electrodes 28 are provided, in order to make a series connection between the thermoelectric conversion elements connected in parallel, as shown in FIG. 1A, the positions at which the through electrodes 28 are provided between adjacent thermoelectric conversion module substrates 20 are reversed in the y direction in FIG. 1A. In this case, it is possible to realize the arrangement by rotating the thermoelectric conversion module substrate 20 having the same configuration by 180°.

In the thermoelectric conversion module 12, it is not required to provide an insulating layer or the like between the P-type thermoelectric conversion elements 24 and between the N-type thermoelectric conversion elements 26. Therefore, it is possible to maximize power generation output by suppressing a decrease in power generation output. Further, since it is not required to provide an insulating layer or the like and the thermoelectric conversion module substrates 20 can be arranged close to each other, high density integration can be achieved. In addition, since it is not required to provide an insulating layer or the like, the device cost and the manufacturing cost can be reduced.

In the thermoelectric conversion module 12, the upper electrode 29 is provided. However, the present invention is not limited to the configuration shown in FIG. 1A.

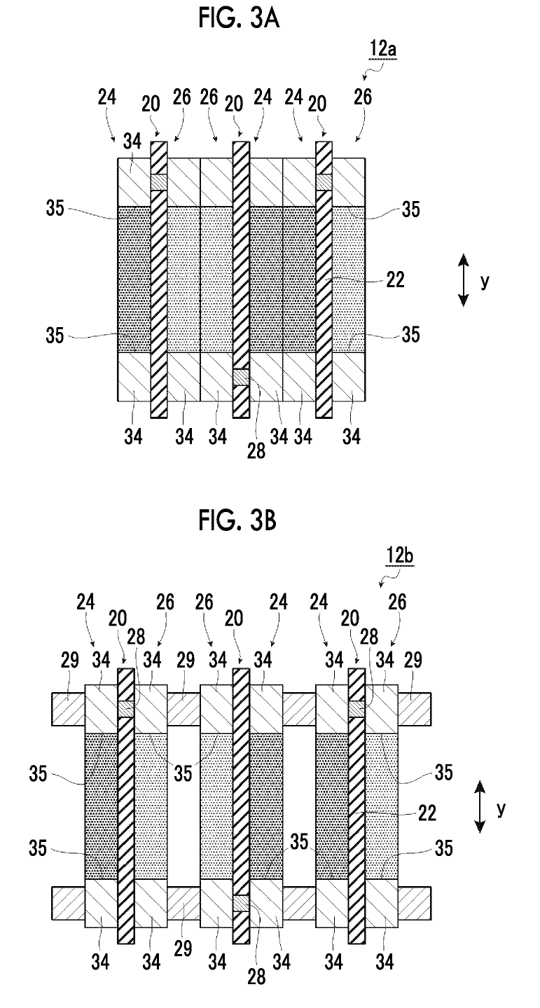

FIG. 3A is a schematic view showing a first modification example of the thermoelectric conversion module according to the embodiment of the present invention and FIG. 3B is a schematic view showing a second modification example of the thermoelectric conversion module according to the embodiment of the present invention. In a thermoelectric conversion module 12a shown in FIG. 3A and a thermoelectric conversion module 12b shown in FIG. 3B, the same symbols are attached to the same constitutional components as in the thermoelectric conversion module 12 shown in FIG. 1A and the detailed descriptions thereof are omitted.

For example, as in the thermoelectric conversion module 12a shown in FIG. 3A, the connection electrode 34 of one facing P-type thermoelectric conversion element 24 and the connection electrode 34 of the other facing P-type thermoelectric conversion element 24 may be electrically connected by bringing the thermoelectric conversion module substrates 20 into direct contact with each other without providing the upper electrode 29. In this case, the P-type thermoelectric conversion elements 24 are electrically connected to each other in parallel.

In a case of the N-type thermoelectric conversion element 26, similar to the case of the P-type thermoelectric conversion element 24, the connection electrode 34 of one facing N-type thermoelectric conversion element 26 and the connection electrode 34 of the other facing N-type thermoelectric conversion element 26 may be electrically connected. In this case, the N-type thermoelectric conversion elements 26 are also electrically connected to each other in parallel.

In the thermoelectric conversion module of the present invention, the thermoelectric conversion module substrates 20 are laminated by arranging the P-type thermoelectric conversion elements 24 to face each other and arranging the N-type thermoelectric conversion elements 26 to face each other. That is, the thermoelectric conversion layers having the same polarity are arranged to face each other and the thermoelectric conversion module substrates 20 are laminated. Therefore, as in the thermoelectric conversion module 12a shown in FIG. 3A, even in a case where the thermoelectric conversion layers or the connection electrodes 34 are brought into close contact with each other, a short circuit is not generated.

In the thermoelectric conversion module 12a shown in FIG. 3A, compared to the thermoelectric conversion module 12, the thermoelectric conversion module substrates 20 can be arranged closer to each other, and thus higher density integration can be achieved. In addition, even in a state in which a member is damaged and disconnected, compensation can be made by the thermoelectric conversion layers and/or the connection electrodes which are in contact with each other, and thus the failure of the thermoelectric conversion module 12a can be prevented.

As in the thermoelectric conversion module 12b shown in FIG. 3B, the position at which the upper electrode 29 is provided may be changed. In the thermoelectric conversion module 12b in FIG. 3B, the upper electrode 29 is provided only on the connection electrode 34. In this case, the P-type thermoelectric conversion elements 24 are electrically connected to each other in parallel and thus the P-type thermoelectric conversion elements 24 can be electrically connected to each other in parallel.

As in the thermoelectric conversion module 12 shown in FIG. 1A, in a case where the upper electrode 29 is provided so as to cover the connection portion 35 of the connection electrode 34 and the thermoelectric conversion layer, the electrically connected state of the connection electrode 34 and the thermoelectric conversion layer can be further improved, and thus this case is preferable.

Next, a method of manufacturing the thermoelectric conversion module 12 will be described.

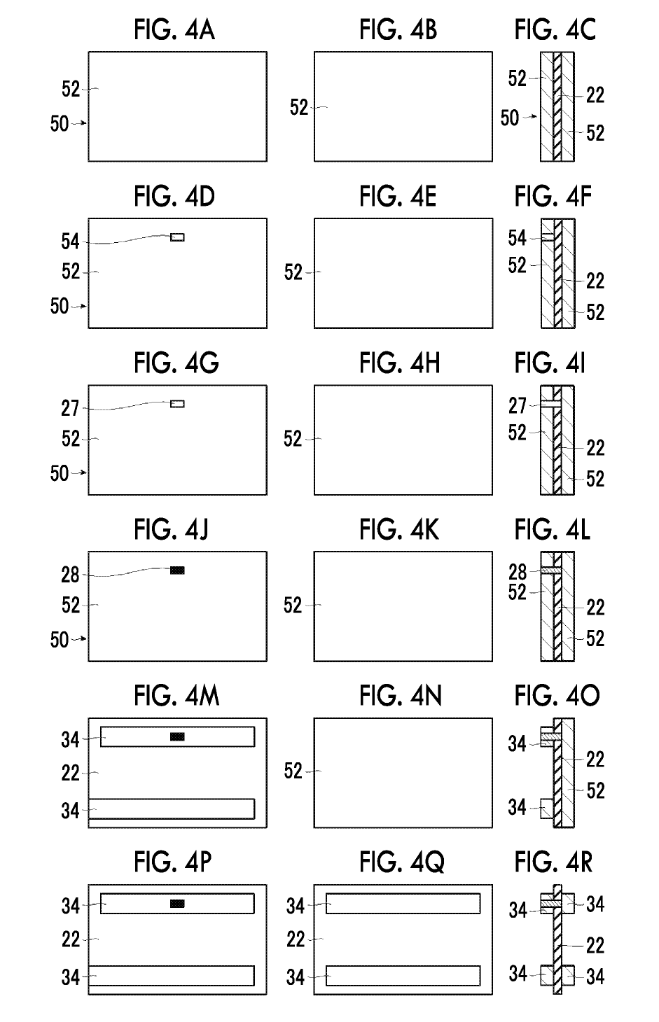

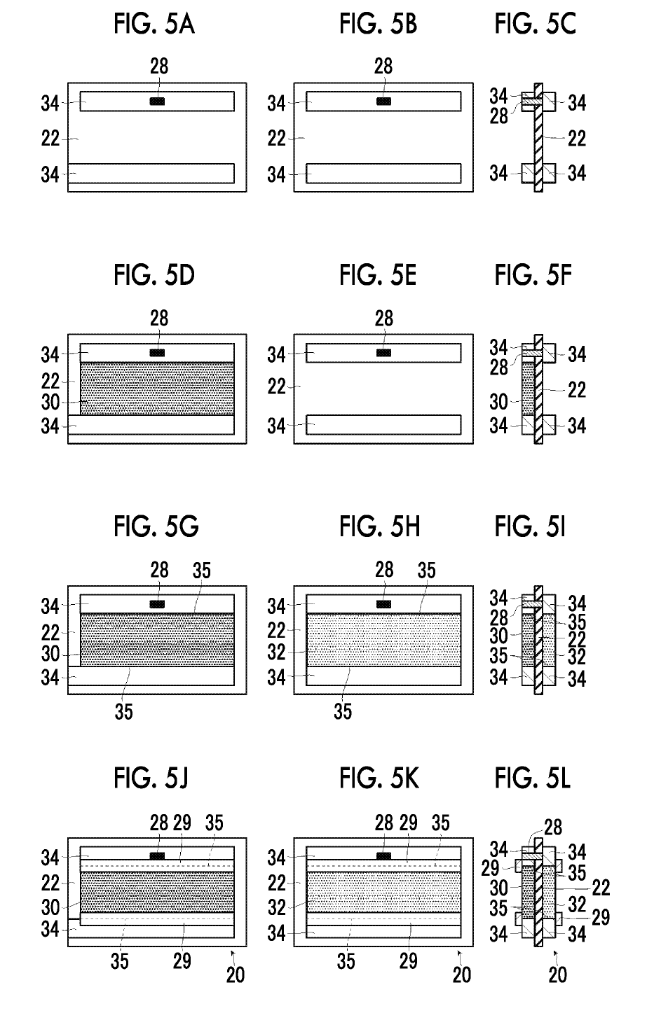

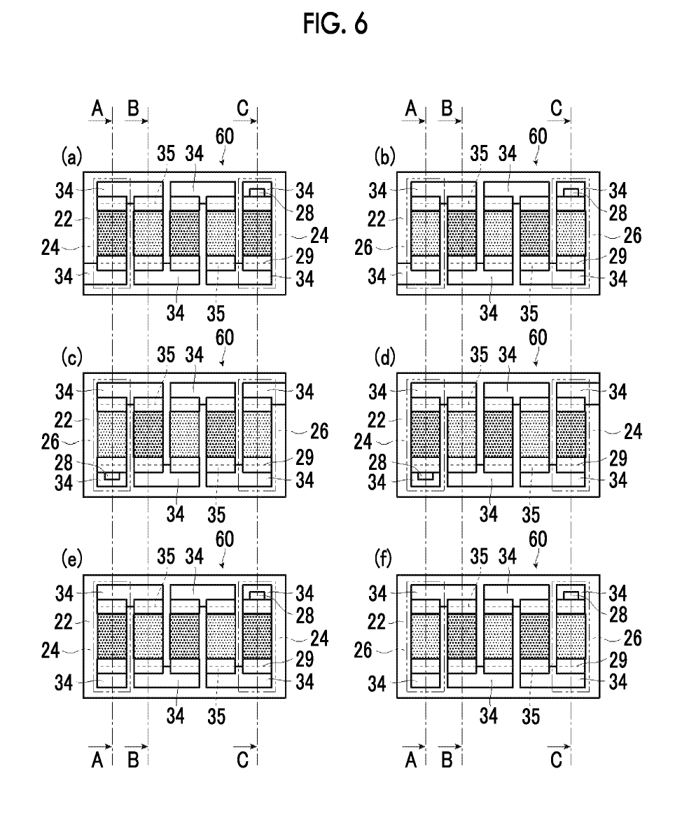

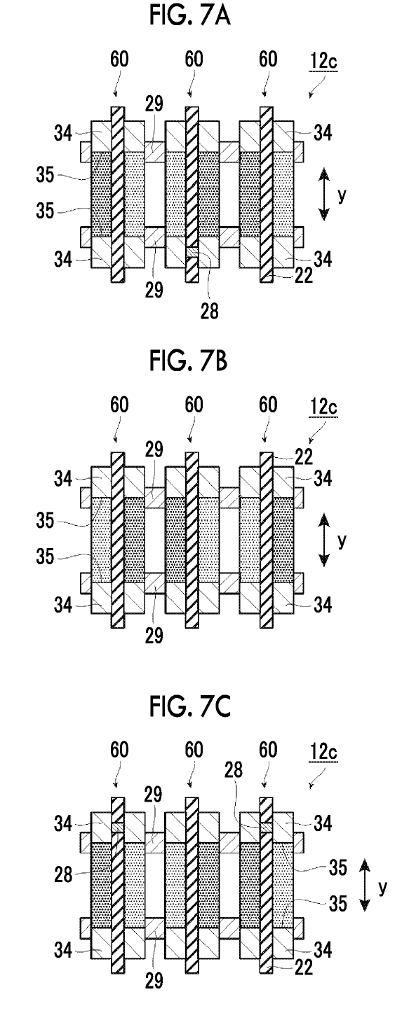

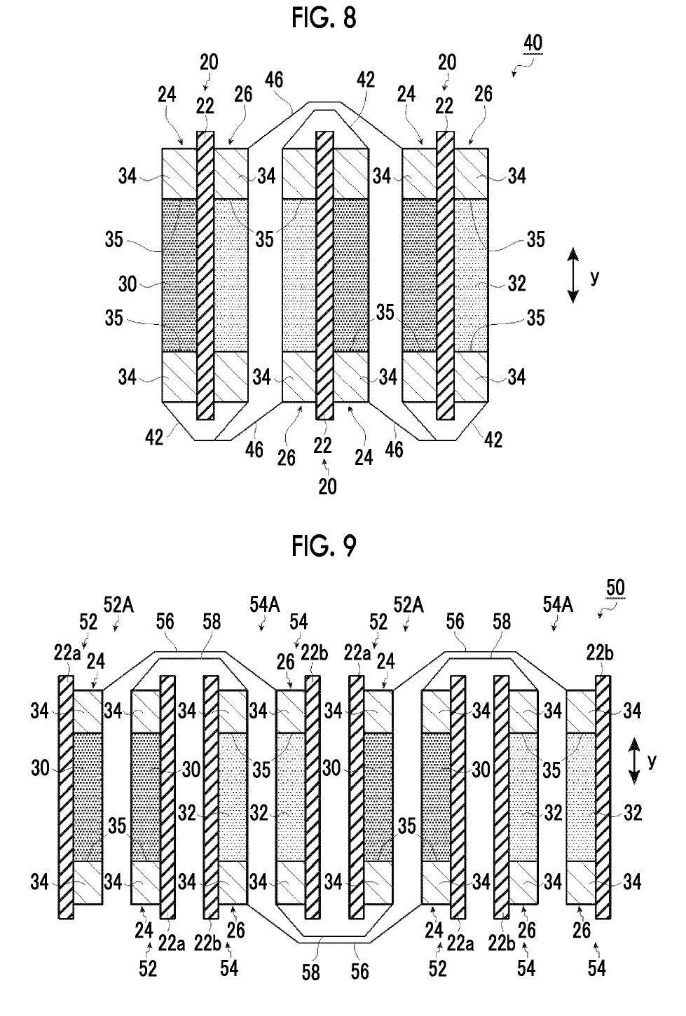

FIGS. 4A to 4R are schematic views showing a step order of a method of manufacturing a connection electrode of the thermoelectric conversion module according to the embodiment of the present invention and FIGS. 5A to 5L are schematic views showing a step order of a method of manufacturing the thermoelectric conversion module according to the embodiment of the present invention.

In FIGS. 4A to 4R, FIGS. 4A to 4C, FIGS. 4D to 4F, FIGS. 4G to 4I, FIGS. 4J to 4L, FIGS. 4M to 4O, and FIGS. 4P to 4R respectively show the same step and the respective three drawings form a set.

In addition, in FIGS. 5A to 5L, FIGS. 5A to 5C, FIGS. 5D to 5F, FIGS. 5G to 5I, and FIGS. 5J to 5L respectively show the same step and the respective three drawings form a set. FIGS. 4P to 4R are drawings showing the same state as in FIGS. 5A to 5C.

First, a method of manufacturing the connection electrode 34 will be described.

As shown in FIGS. 4A to 4C, a copper substrate 50 in which a copper layer 52 is formed on both surfaces of the insulating substrate 22 is prepared.

Next, as shown in FIGS. 4D to 4F, a hole 54 which reaches the insulating substrate 22 is formed at the position where the through hole 27 is formed in one copper layer 52 of the copper substrate 50, for example, by combining a photolithography method and etching.

Next, as shown in FIGS. 4G to 4I, the through hole 27 which passes through the insulating substrate 22 and reaches the other copper layer 52 is formed by, for example, etching the insulating substrate 22 facing the hole 54.

Next, as shown in FIGS. 4J to 4L, the through electrode 28 is formed by subjecting the through hole 27 to, for example, through-hole plating of copper. For example, the through-hole plating is electroless plating and/or electrolytic plating.

Next, as shown in FIGS. 4M to 4O, a pair of separated connection electrodes 34 is formed as a pattern on the copper layer in which the above-described hole 54 is formed by, for example, combining a photolithography method and etching.

Next, as shown in FIGS. 4P to 4R, a pattern of a pair of separated connection electrodes 34 is formed on the copper layer 52, on which the connection electrodes 34 are not formed, by, for example, combining a photolithography method and etching. Thus, the connection electrodes 34 including the connection electrodes 34 electrically connected to each other by the through electrode 28 are formed on both surfaces of the insulating substrate 22.

Next, as described above, with respect to the insulating substrate 22 on which the connection electrodes 34 are formed (refer to FIGS. 5A to 5C), as shown in FIGS. 5D to 5F, the P-type thermoelectric conversion layer 30 is formed on one surface of the insulating substrate 22 by, for example, a printing method using a metal mask.

Next, as shown in FIGS. 5G to 5I, the N-type thermoelectric conversion layer 32 is formed on the other surface of the insulating substrate 22 by, for example, a printing method using a metal mask. Thus, the thermoelectric conversion module substrate 20 is formed.

A plurality of thermoelectric conversion module substrates 20 are formed and then, as shown in FIGS. 5J to 5L, for example, cream solder is formed layers by, for example, a printing method using a metal mask so as to cover the connection portions of the connection electrodes 34 and the thermoelectric conversion layers on both surfaces of the insulating substrate 22.

The thermoelectric conversion module substrates 20 are laminated such that the P-type thermoelectric conversion elements 24 and the N-type thermoelectric conversion elements 26 are made to face each other and a state in which the plurality of thermoelectric conversion module substrates 20 are laminated is held using a tool.

Next, solder reflow is performed to electrically connect the P-type thermoelectric conversion elements 24 and the N-type thermoelectric conversion elements 26 in parallel by the upper electrode 29. Thus, the thermoelectric conversion module 12 is formed.

Next, another thermoelectric conversion module according to the embodiment of the present invention will be described.

(a) of FIG. 6 is a schematic view showing a surface of a first thermoelectric conversion module substrate of another thermoelectric conversion module according to the embodiment of the present invention, (b) of FIG. 6 is a schematic view showing a rear surface of the first thermoelectric conversion module substrate of another thermoelectric conversion module according to the embodiment of the present invention, (c) of FIG. 6 is a schematic view showing a surface of a second thermoelectric conversion module substrate of another thermoelectric conversion module according to the embodiment of the present invention, (d) of FIG. 6 is a schematic view showing a rear surface of the second thermoelectric conversion module substrate of another thermoelectric conversion module according to the embodiment of the present invention, (e) of FIG. 6 is a schematic view showing a surface of a third thermoelectric conversion module substrate of another thermoelectric conversion module according to the embodiment of the present invention, and (f) of FIG. 6 is a schematic view showing a rear surface of the third thermoelectric conversion module substrate of another thermoelectric conversion module according to the embodiment of the present invention.

FIG. 7A is a schematic cross-sectional view showing a first cross section of another thermoelectric conversion module according to the embodiment of the present invention, FIG. 7B is a schematic cross-sectional view showing a second cross section of another thermoelectric conversion module according to the embodiment of the present invention, and FIG. 7C is a schematic cross-sectional view showing a third cross section of another thermoelectric conversion module according to the embodiment of the present invention.

In Figs. (a) of 6 to 6 and 7A to 7C, the same symbols are attached to the same constitutional components as in the thermoelectric conversion module 12 shown in FIGS. 1A and 2A to 2F and the detailed descriptions thereof are omitted.

As another thermoelectric conversion module 12c is compared to the thermoelectric conversion module 12, the configuration of another thermoelectric conversion module 12c is the same as the configuration of the thermoelectric conversion module 12 except that the configuration of a thermoelectric conversion module substrate 60 is different. Thus, the detailed descriptions thereof are omitted.

In another thermoelectric conversion module 12c, a case in which three thermoelectric conversion module substrates 60 are provided will be described as an example.

In addition, the first cross section of FIG. 7A refers to a cross section taken along line A-A of (a) to (f) of FIG. 6, the second cross section of FIG. 7B refers to a cross section taken along line B-B of (a) to (1) of FIG. 6, and the third cross section of FIG. 7C refers to a cross section taken along line C-C of (a) to (f) of FIG. 6.

In the thermoelectric conversion module substrate 60 of another thermoelectric conversion module 12c, as shown in (a) to (f) of FIG. 6, a plurality of P-type thermoelectric conversion elements 24 and a plurality of N-type thermoelectric conversion elements 26 are provided on one surface and the other surface of the insulating substrate 22 respectively such that the thermoelectric conversion elements are electrically connected to each other in series without forming the P-type thermoelectric conversion element 24 on one surface of the insulating substrate 22, and forming the N-type thermoelectric conversion element 26 on the other surface of the insulating substrate 22. The P-type thermoelectric conversion element 24 and the N-type thermoelectric conversion element 26 are connected in series by the connection electrodes 34.

In a case where the size of the insulating substrate 22 is identical, the P-type thermoelectric conversion element 24 and the N-type thermoelectric conversion element 26 of another thermoelectric conversion module 12c are smaller than the P-type thermoelectric conversion element and the N-type thermoelectric conversion element in the thermoelectric conversion module 12 shown in FIG. 1.

In another thermoelectric conversion module 12c, as shown in FIGS. 7A to 7C, similar to the thermoelectric conversion module 12, the thermoelectric conversion module substrates 60 are laminated such that the plurality of P-type thermoelectric conversion elements 24 and the plurality of N-type thermoelectric conversion elements 26 are made to face each other, that is, the thermoelectric conversion elements having the same polarity are made to face each other.

As in another thermoelectric conversion module 12c, by providing the plurality of P-type thermoelectric conversion elements 24 and the plurality of N-type thermoelectric conversion elements 26, compared to the thermoelectric conversion module 12, the number of thermoelectric conversion elements which are connected to each other in series is increased and a high voltage can be obtained.

In another thermoelectric conversion module 12c, as in the thermoelectric conversion module 12, the upper electrode 29 is also provided. However, as in the thermoelectric conversion module 12, as shown in FIG. 3A, the upper electrode 29 may not be provided. In addition, as shown in FIG. 3B, the upper electrode 29 may be provided only on the connection electrode 34.

FIG. 8 is a schematic view showing a thermoelectric conversion module according to another embodiment of the present invention.

In FIG. 8, the same symbols are attached to the same constitutional components as in the thermoelectric conversion module 12 shown in FIGS. 1A and 2A to 2F and the detailed descriptions thereof are omitted.

A thermoelectric conversion module 40 shown in FIG. 8 has the same configuration as the thermoelectric conversion module 12 except that the electrical connection method of the P-type thermoelectric conversion element 24 and the N-type thermoelectric conversion element 26 is different compared to the thermoelectric conversion module 12, and thus the detailed descriptions thereof are omitted.

In the thermoelectric conversion module 40, a case where three thermoelectric conversion module substrates 20 are provided will be described as an example.

In the above-described thermoelectric conversion module 12 or the like, the P-type thermoelectric conversion element 24 and the N-type thermoelectric conversion element 26 of the thermoelectric conversion module substrate 20 are electrically connected using the through electrode 28 and the P-type thermoelectric conversion elements 24 and the N-type thermoelectric conversion elements 26 of the laminated thermoelectric conversion module substrates 20 are electrically connected to each other in parallel by the upper electrode 29 electrically connected to the connection electrode 34.

In contrast, in the thermoelectric conversion module 40 shown in FIG. 8, the P-type thermoelectric conversion element 24 and the N-type thermoelectric conversion element 26 of the thermoelectric conversion module substrate 20 are electrically connected to each other through the connection electrodes 34 by a connection wiring 42 electrically connected to the connection electrodes 34 without using the through electrode 28.

In addition, in the thermoelectric conversion module 40 shown in FIG. 8, the P-type thermoelectric conversion elements 24 and the N-type thermoelectric conversion elements 26 of the laminated thermoelectric conversion module substrates 20 are electrically connected to each other through the connection electrodes 34 by a connection wiring 46 electrically connected to the connection electrode 34 without using the upper electrode 29.

In the thermoelectric conversion module substrates 20 on both sides, some parts are shared by the connection wiring 42 and the connection wiring 46.

Accordingly, in the thermoelectric conversion module 40 shown in FIG. 8, the P-type thermoelectric conversion elements 24 and the N-type thermoelectric conversion elements 26 are not connected to each other in parallel and two thermoelectric conversion modules in which the P-type thermoelectric conversion elements 24 and the N-type thermoelectric conversion elements 26 are connected to each other in series are connected to each other in parallel.

According to the present invention, even in a case where the thermoelectric conversion elements are connected to each other without using the through electrode 28 and the upper electrode 29 as described above, a thermoelectric conversion module exhibiting high power generation output can be obtained.

Even in the configuration using a connection wiring as in the thermoelectric conversion module 40 shown in FIG. 8, for example, the P-type thermoelectric conversion element 24 and the N-type thermoelectric conversion element 26 of the thermoelectric conversion module substrate 20 may be connected by using the through electrode 28 instead of using the connection wiring 42. That is, the through electrode 28 which connects the P-type thermoelectric conversion element 24 and the N-type thermoelectric conversion element 26 of the thermoelectric conversion module substrate 20 and the connection wiring 46 which connects the P-type thermoelectric conversion elements 24 and the N-type thermoelectric conversion elements 26 of the laminated thermoelectric conversion module substrates 20 may be used.

In the same manner, the P-type thermoelectric conversion elements 24 or the N-type thermoelectric conversion elements 26 of the laminated thermoelectric conversion module substrates 20 may be connected to each other using the upper electrode 29 instead of using the connection wiring 46. That is, the connection wiring 42 which connects the P-type thermoelectric conversion element 24 and the N-type thermoelectric conversion element 26 of the thermoelectric conversion module substrate 20, and the upper electrode 29 which connects the P-type thermoelectric conversion elements 24 or the N-type thermoelectric conversion elements 26 of the laminated thermoelectric conversion module substrates 20 may be used.

In addition, as shown in FIG. 3A, in the thermoelectric conversion module 40 shown in FIG. 8, the facing P-type thermoelectric conversion elements 24 or the facing N-type thermoelectric conversion elements 26 may be also brought into contact with each other.

FIG. 9 is a schematic view showing a thermoelectric conversion module according to an embodiment of a second invention having a similar but simpler configuration as the above thermoelectric conversion module of the first invention.

In FIG. 9, the same symbols are attached to the same constitutional components as in the thermoelectric conversion module 12 shown in FIGS. 1A and 2A to 2F and the detailed descriptions thereof are omitted.

All of the thermoelectric conversion module substrates 20 constituting the above-described thermoelectric conversion module 12 or the like have the P-type thermoelectric conversion element 24 on one surface of the insulating substrate 22 and the N-type thermoelectric conversion element 26 on the other surface thereof

In contrast, a thermoelectric conversion module 50 shown in FIG. 9 includes a P-type thermoelectric conversion module substrate 52 in which a P-type thermoelectric conversion element 24 having a P-type thermoelectric conversion layer 30 and a pair of connection electrodes 34 which are electrically connected to the P-type thermoelectric conversion layer 30 is formed on one surface of a first insulating substrate 22a, and an N-type thermoelectric conversion module substrate 54 in which an N-type thermoelectric conversion element 26 having an N-type thermoelectric conversion layer 32 and a pair of connection electrodes 34 which are electrically connected to the N-type thermoelectric conversion layer 32 is formed on one surface of a second insulating substrate 22b.

In the thermoelectric conversion module 50 in FIG. 9, a case where four P-type thermoelectric conversion module substrates 52 and four N-type thermoelectric conversion module substrates 54 are respectively provided will be described as an example.

In the thermoelectric conversion module 50, a P-type laminate 52A is formed by laminating two P-type thermoelectric conversion module substrates 52 such that the P-type thermoelectric conversion elements 24 are arranged to face each other, and an N-type laminate 54A is formed by laminating two N-type thermoelectric conversion module substrates 54 such that the N-type thermoelectric conversion elements 26 are arranged to face each other.

The thermoelectric conversion module 50 is formed by alternately laminating the P-type laminate 52A and the N-type laminate 54A.

Further, in adjacent P-type laminate 52A and N-type laminate 54A of the laminated P-type laminate 52A and N-type laminate 54A, the P-type thermoelectric conversion element 24 of one P-type thermoelectric conversion module substrate 52 of the P-type laminate 52A and the N-type thermoelectric conversion element 26 of one N-type thermoelectric conversion module substrate 54 of the N-type laminate 54A are electrically connected to each other through the connection electrodes 34 by the connection wiring 56. Also, the P-type thermoelectric conversion element 24 of the other P-type thermoelectric conversion module substrate 52 of the P-type laminate 52A and the N-type thermoelectric conversion element 26 of the other N-type thermoelectric conversion module substrate 54 of the N-type laminate 54A are electrically connected to each other through the connection electrodes 34 by the connection wiring 56.

Thermoelectric conversion module 12 in which the thermoelectric conversion elements are formed on both surfaces of the insulating substrate 22 or the like has a configuration in which patterns of “insulating substrate 22—P-type thermoelectric conversion layer 30—P-type thermoelectric conversion layer 30—insulating substrate 22—N-type thermoelectric conversion layer 32—N-type thermoelectric conversion layer 32” are repeated in a lamination direction of the thermoelectric conversion module substrate.

In contrast, the thermoelectric conversion module 50 shown in FIG. 9 in which the thermoelectric conversion element is formed on only one surface of the insulating substrate has a configuration in which patterns of “first insulating substrate 22a—P-type thermoelectric conversion layer 30—P-type thermoelectric conversion layer 30—first insulating substrate 22a—second insulating substrate 22b—N-type thermoelectric conversion layer 32—N-type thermoelectric conversion layer 32—second insulating substrate 22b” are repeated in the lamination direction of the thermoelectric conversion module substrate.

Thus, in the thermoelectric conversion module 50, a simple configuration in which the thermoelectric conversion element is formed on only one surface of the insulating substrate is realized, the configuration having two thermoelectric conversion modules in which the P-type thermoelectric conversion element 24 and the N-type thermoelectric conversion element 26 are connected to each other in series.

In the thermoelectric conversion module 50 shown in FIG. 9, as shown in FIG. 3A, the facing P-type thermoelectric conversion elements 24 and the facing N-type thermoelectric conversion elements 26 may be also brought into contact with each other.

Hereinafter, the constitutional members of the above-described thermoelectric conversion modules 12, 12a, and 12b, another thermoelectric conversion module 12c, the thermoelectric conversion module 40, and the thermoelectric conversion module 50 will be described in more detail.

Since the thermoelectric conversion module 12, the thermoelectric conversion module 12a, the thermoelectric conversion module 12b, another thermoelectric conversion module 12c, the thermoelectric conversion module 40, and the thermoelectric conversion module 50 basically have the same constitutional members, the thermoelectric conversion module 12 will be described representatively.

The insulating substrate 22 (first insulating substrate 22a and second insulating substrate 22b) has the P-type thermoelectric conversion element 24 and(or) the N-type thermoelectric conversion element 26 formed thereon and functions as a support for the P-type thermoelectric conversion element 24 and the N-type thermoelectric conversion element 26. Since the voltage is generated in the thermoelectric conversion module 12, the insulating substrate 22 is required to have electrically insulating properties, and a substrate having electrically insulating properties is used for the insulating substrate 22. The electrically insulating properties required for the insulating substrate 22 are to prevent a short circuit from occurring due to the voltage generated in the thermoelectric conversion module 12 or the like. Regarding the insulating substrate 22, a substrate is appropriately selected according to the voltage generated by the thermoelectric conversion module 12.

For example, the insulating substrate 22 is a plastic substrate. For the plastic substrate, a plastic film can be used.

Specific examples of the plastic film that can be used include films or sheet-like materials or plate-like materials of polyester resins such as polyethylene terephthalate, polyethylene isophthalate, polyethylene naphthalate, polybutylene terephthalate, poly(1,4-cyclohexylene dimethylene terephthalate), and polyethylene-2,6-naphthalenedicarboxylate, resins such as polyimide, polycarbonate, polypropylene, polyethersulfone, cycloolefin polymer, and polyether ether ketone (PEEK), triacetyl cellulose (TAC), glass epoxy, and liquid crystal polyester.

Among these, from the viewpoint of thermal conductivity, heat resistance, solvent resistance, ease of availability, and economy, films of polyimide, polyethylene terephthalate, polyethylene naphthalate, and the like are suitably used for the insulating substrate 22.

Hereinafter, the P-type thermoelectric conversion layer 30 and the N-type thermoelectric conversion layer 32 will be described.

As the thermoelectric conversion material constituting the P-type thermoelectric conversion layer 30 and the N-type thermoelectric conversion layer 32, for example, nickel or a nickel alloy may be used.

As the nickel alloy, various nickel alloys that generate power by causing a temperature difference can be used. Specific examples thereof include nickel alloys mixed with one or two or more of vanadium, chromium, silicon, aluminum, titanium, molybdenum, manganese, zinc, tin, copper, cobalt, iron, magnesium, and zirconium.

In a case where nickel or a nickel alloy is used for the P-type thermoelectric conversion layer 30 and the N-type thermoelectric conversion layer 32, the nickel content in the P-type thermoelectric conversion layer 30 and the N-type thermoelectric conversion layer 32 is preferably 90% by atom or more and more preferably 95% by atom or more, and the thermoelectric conversion layers are particularly preferably formed of nickel. The P-type thermoelectric conversion layer 30 and the N-type thermoelectric conversion layer 32 formed of nickel include inevitable impurities.

As the thermoelectric conversion material for the P-type thermoelectric conversion layer 30, chromel having Ni and Cr as main components is typically used. As the thermoelectric material for the N-type thermoelectric conversion layer 32, constantan having Cu and Ni as main components is typically used.

In addition, in a case where nickel or a nickel alloy is used for the P-type thermoelectric conversion layer 30 and the N-type thermoelectric conversion layer 32, and also nickel or a nickel alloy is used for an electrode, the P-type thermoelectric conversion layer 30, the N-type thermoelectric conversion layer 32, and the connection electrode 34 may be integrally formed.

As other thermoelectric materials for the P-type thermoelectric conversion layer 30 and the N-type thermoelectric conversion layer 32, for example, the following materials may be used. Incidentally, the components in parentheses indicate the material composition. Examples of the material include BiTe-based materials (BiTe, SbTe, BiSe and compounds thereof), PbTe-based materials (PbTe, SnTe, AgSbTe, GeTe and compounds thereof), Si—Ge-based materials (Si, Ge, SiGe), silicide-based materials (FeSi, MnSi, CrSi), skutterudite-based materials (compounds represented by MX₃ or RM₄X₁₂, where M equals Co, Rh, or Ir, X equals As, P, or Sb, and R equals La, Yb, or Ce), transition metal oxides (NaCoO, CaCoO, ZnInO, SrTiO, BiSrCoO, PbSrCoO, CaBiCoO, BaBiCoO), zinc antimony based compounds (ZnSb), boron compounds (CeB, BaB, SrB, CaB, MgB, VB, NiB, CuB, LiB), cluster solids (B cluster, Si cluster, C cluster, AlRe, AlReSi), and zinc oxides (ZnO). In addition, the film formation method is arbitrary and a film formation method such as a sputtering method, a vapor deposition method, a CVD method, a plating method, or an aerosol deposition method can be used.

In addition, for the thermoelectric conversion material used for the P-type thermoelectric conversion layer 30 and the N-type thermoelectric conversion layer 32, various configurations using known thermoelectric conversion materials including an organic material as a material that can form a film by coating or printing and can be made into paste can be used.

Specific examples of the thermoelectric conversion material from which the P-type thermoelectric conversion layer 30 and the N-type thermoelectric conversion layer 32 as described above can be obtained include an organic thermoelectric conversion material such as a conductive polymer or a conductive nanocarbon material may be used.

Examples of the conductive polymer include a polymer compound having a conjugated molecular structure (conjugated polymer). Specific examples thereof include known π-conjugated polymers such as polyaniline, polyphenylene vinylene, polypyrrole, polythiophene, polyfluorene, acetylene, and polyphenylene. Particularly, polydioxythiophene can be suitably used.

Specific examples of the conductive nanocarbon material include carbon nanotubes (hereinafter, also referred to as CNTs), carbon nanofiber, graphite, graphene, and carbon nanoparticles. These may be used singly or in combination of two or more thereof. Among these, from the viewpoint of further improving thermoelectric properties, CNT is preferably used.

CNT is categorized into single layer CNT of one carbon film (graphene sheet) wound in the form of a cylinder, double layer CNT of two graphene sheets wound in the form of concentric circles, and multilayer CNT of a plurality of graphene sheets wound in the form of concentric circles. In the present invention, each of the single layer CNT, the double layer CNT, and the multilayer CNT may be used singly, or two or more thereof may be used in combination. Particularly, the single layer CNT and the double layer CNT excellent in conductivity and semiconductor characteristics are preferably used, and the single layer CNT is more preferably used.

The single layer CNT may be semiconductive or metallic. Furthermore, semiconductive CNT and metallic CNT may be used in combination. In a case where both of the semiconductive CNT and the metallic CNT are used, a content ratio between the CNTs in a composition can be appropriately adjusted according to the use of the composition. In addition, CNT may contain a metal or the like, and CNT containing fullerene molecules and the like may be used.

An average length of CNT is not particularly limited and can be appropriately selected according to the use of the composition. Specifically, from the viewpoint of ease of manufacturing, film formability, conductivity, and the like, the average length of CNT is preferably 0.01 to 2,000 μm, more preferably 0.1 to 1,000 μm, and particularly preferably 1 to 1,000 μm, though the average length also depends on an inter-electrode distance.

A diameter of CNT is not particularly limited. From the viewpoint of durability, transparency, film formability, conductivity, and the like, the diameter is preferably 0.4 to 100 nm, more preferably 50 nm or less, and particularly preferably 15 nm or less.

Particularly, in a case where the single layer CNT is used, the diameter is preferably 0.5 to 2.2 nm, more preferably 1.0 to 2.2 nm, and particularly preferably 1.5 to 2.0 nm.

The CNT contained in the obtained conductive composition contains defective CNT in some cases. Because the defectiveness of the CNT deteriorates the conductivity of the composition, it is preferable to reduce the amount of the defective CNT. The amount of defectiveness of the CNT in the composition can be estimated by a G/D ratio between a G band and a D band in a Raman spectrum. In a case where the G/D ratio is high, the composition can be assumed to be a CNT material with a small amount of defectiveness. The G/D ratio of the composition is preferably 10 or higher and more preferably 30 or higher.

In addition, modified or treated CNT can also be used. Examples of the modification or treatment method include a method of incorporating a ferrocene derivative or nitrogen-substituted fullerene (azafullerene) into CNT, a method of doping CNT with an alkali metal (potassium or the like) or a metallic element (indium or the like) by an ion doping method, and a method of heating CNT in a vacuum.

In a case where CNT is used, in addition to the single layer CNT or the multilayer CNT, nanocarbons such as carbon nanohorns, carbon nanocoils, carbon nanobeads, graphite, graphene, amorphous carbon, and the like may be contained in the composition.

In a case where CNT is used in the P-type thermoelectric conversion layer or the N-type thermoelectric conversion layer, it is preferable that CNT includes a P-type dopant or an N-type dopant.

### P-Type Dopant

Examples of the P-type dopant include halogen (iodine, bromine, or the like), Lewis acid (PF₅, AsF₅, or the like), protonic acid (hydrochloric acid, sulfuric acid, or the like), transition metal halide (FeCl₃, SnCl₄, or the like), a metal oxide (molybdenum oxide, vanadium oxide, or the like), and an organic electron-accepting material. Examples of the organic electron-accepting material suitably include a tetracyanoquinodimethane (TCNQ) derivative such as 2,3,5,6-tetrafluoro-7,7,8,8-tetracyanoquinodimethane, 2,5-dimethyl-7,7,8,8-tetracyanoquinodimethane, 2-fluoro-7,7,8,8-tetracyanoquinodimethane, or 2,5-difluoro-7,7,8,8-tetracyanoquinodimethane, a benzoquinone derivative such as 2,3-dichloro-5,6-dicyano-p-benzoquinone or tetrafluoro-1,4-benzoquinone, 5,8H-5,8-bis(dicyanomethylene)quinoxaline, dipyrazino[2,3-f:2′,3′-h]quinoxaline-2,3,6,7,10,11-hexacarbonitrile, and the like.

Among these, from the viewpoint of the stability of the materials, the compatibility with CNT, and the like, organic electron-accepting materials such as a tetracyanoquinodimethane (TCNQ) derivative or a benzoquinone derivative are suitably exemplified.

The P-type dopant and the N-type dopant may be used singly or in combination of two or more thereof

### N-Type Dopant

As the N-type dopant, known materials such as (1) alkali metals such as sodium and potassium, (2) phosphines such as triphenylphosphine and ethylenebis(diphenylphosphine), (3) polymers such as polyvinyl pyrrolidone and polyethylene imine, and the like can be used. In addition, for examples, polyethylene glycol type higher alcohol ethylene oxide adducts, ethylene oxide adducts of phenol, naphthol or the like, fatty acid ethylene oxide adducts, polyhydric alcohol fatty acid ester ethylene oxide adducts, higher alkylamine ethylene oxide adducts, fatty acid amide ethylene oxide adducts, ethylene oxide adducts of fat, polypropylene glycol ethylene oxide adducts, dimethylsiloxane-ethylene oxide block copolymers, dimethylsiloxane-(propylene oxide-ethylene oxide) block copolymers, fatty acid esters of polyhydric alcohol type glycerol, fatty acid esters of pentaerythritol, fatty acid esters of sorbitol and sorbitan, fatty acid esters of sucrose, alkyl ethers of polyhydric alcohols and fatty acid amides of alkanolamines. Further, acetylene glycol-based and acetylene alcohol-based oxyethylene adducts, fluorine-based and silicon-based surfactants and the like can be also used. As the N-type dopant, a commercially available product can be used.

In the thermoelectric conversion element, the thermoelectric conversion layer obtained by dispersing the aforementioned thermoelectric conversion material in a resin material (binder) is suitably used.

Among these, the thermoelectric conversion layer obtained by dispersing a conductive nanocarbon material in a resin material is more suitably exemplified. Especially, the thermoelectric conversion layer obtained by dispersing CNT in a resin material is particularly suitably exemplified because this makes it possible to obtain high conductivity and the like.

As the resin material, various known nonconductive resin materials (polymers) can be used.

Specifically, it is possible to use various known resin materials such as a vinyl compound, a (meth)acrylate compound, a carbonate compound, an ester compound, an epoxy compound, a siloxane compound, and gelatin.

More specifically, examples of the vinyl compound include polystyrene, polyvinyl naphthalene, polyvinyl acetate, polyvinyl phenol, and polyvinyl butyral. Examples of the (meth)acrylate compound include polymethyl (meth)acrylate, polyethyl (meth)acrylate, polyphenoxy(poly)ethylene glycol (meth)acrylate, and polybenzyl (meth)acrylate. Examples of the carbonate compound include bisphenol Z-type polycarbonate, and bisphenol C-type polycarbonate. Examples of the ester compound include amorphous polyester.

Polystyrene, polyvinyl butyral, a (meth)acrylate compound, a carbonate compound, and an ester compound are preferable, and polyvinyl butyral, polyphenoxy(poly)ethylene glycol (meth)acrylate, polybenzyl (meth)acrylate, and amorphous polyester are more preferable.

In the thermoelectric conversion layer obtained by dispersing a thermoelectric conversion material in a resin material, a quantitative ratio between the resin material and the thermoelectric conversion material may be appropriately set according to the material used, the thermoelectric conversion efficiency required, the viscosity or solid content concentration of a solution exerting an influence on printing, and the like.

As another configuration of the thermoelectric conversion layer in the thermoelectric conversion element, a thermoelectric conversion layer mainly constituted of CNT and a surfactant is also suitably used.

By constituting the thermoelectric conversion layer of CNT and a surfactant, the thermoelectric conversion layer can be formed using a coating composition to which a surfactant is added. Therefore, the thermoelectric conversion layer can be formed using a coating composition in which CNT is smoothly dispersed. As a result, by a thermoelectric conversion layer including a large amount of long and less defective CNT, excellent thermoelectric conversion performance is obtained.

As the surfactant, known surfactants can be used as long as the surfactants function to disperse CNT. More specifically, various surfactants can be used as the surfactant as long as surfactants dissolve in water, a polar solvent, or a mixture of water and a polar solvent and have a group adsorbing CNT.

Accordingly, the surfactant may be ionic or nonionic. Furthermore, the ionic surfactant may be any of cationic, anionic, and amphoteric surfactants.

Examples of the anionic surfactant include an aromatic sulfonic acid-based surfactant such as alkylbenzene sulfonate like dodecylbenzene sulfonate or dodecylphenylether sulfonate, a monosoap-based anionic surfactant, an ether sulfate-based surfactant, a phosphate-based surfactant, a carboxylic acid-based surfactant such as sodium deoxycholate or sodium cholate, and a water-soluble polymer such as carboxymethyl cellulose and a salt thereof (sodium salt, ammonium salt, or the like), a polystyrene sulfonate ammonium salt, or a polystyrene sulfonate sodium salt.

Examples of the cationic surfactant include an alkylamine salt and a quaternary ammonium salt. Examples of the amphoteric surfactant include an alkyl betaine-based surfactant, and an amine oxide-based surfactant.

Further, examples of the nonionic surfactant include a sugar ester-based surfactant such as sorbitan fatty acid ester, a fatty acid ester-based surfactant such as polyoxyethylene resin acid ester, and an ether-based surfactant such as polyoxyethylene alkyl ether.

Among these, an ionic surfactant is preferably used, and cholate or deoxycholate is particularly suitably used.

In the thermoelectric conversion layer, a mass ratio of surfactant/CNT is preferably 5 or less, and more preferably 3 or less.

It is preferable that the mass ratio of surfactant/CNT is 5 or less from the viewpoint that a higher thermoelectric conversion performance or the like is obtained.

If necessary, the thermoelectric conversion layer formed of an organic material may contain an inorganic material such as SiO₂, TiO₂, Al₂O₃, or ZrO₂.

In a case where the thermoelectric conversion layer contains an inorganic material, a content of the inorganic material is preferably 20% by mass or less, and more preferably 10% by mass or less.

In the thermoelectric conversion element, a thickness of the thermoelectric conversion layer, a size of the thermoelectric conversion layer in a plane direction, a proportion of an area of the thermoelectric conversion layer with respect to the insulating substrate along the plane direction, and the like may be appropriately set according to the material forming the thermoelectric conversion layer, the size of the thermoelectric conversion element, and the like.

Next, a method of forming a thermoelectric material layer will be described.

The prepared coating composition which becomes the thermoelectric conversion layer is patterned and applied according to a thermoelectric conversion layer to be formed. The application of the coating composition may be performed by a known method such as a method using a mask or a printing method.

After the coating composition is applied, the coating composition is dried by a method according to the resin material, thereby forming the thermoelectric conversion layer. If necessary, after the coating composition is dried, the coating composition (resin material) may be cured by being irradiated with ultraviolet rays or the like.

Alternatively, the prepared coating composition which becomes the thermoelectric conversion layer is applied to the entire surface of the insulating substrate and dried, and then the thermoelectric conversion layer may be formed as a pattern by etching or the like.

In order to form the thermoelectric conversion layers on both surfaces of the insulating substrate, the layer may be formed on one surface by printing by any of the above-described methods and then the layer may be formed on the rear surface in the same manner.

In a case of the thermoelectric conversion modules 12, 12a, and 12b, the P-type thermoelectric material layer is formed as a pattern on one surface of the insulating substrate 22 and then the N-type thermoelectric material layer is formed on the other surface of the insulating substrate 22 as a pattern. The pattern formation order of the P-type thermoelectric material layer and the N-type thermoelectric material layer may be reversed.

In a case of another thermoelectric conversion module 12c, the P-type thermoelectric material layer is formed as a pattern on one surface of the insulating substrate 22 and then the N-type thermoelectric material layer is formed as a pattern.

Next, the P-type thermoelectric material layer is formed as a pattern on the other surface of the insulating substrate 22 and then the N-type thermoelectric material layer is formed as a pattern. The pattern formation order of the P-type thermoelectric material layer and the N-type thermoelectric material layer may be reversed.

The thermoelectric conversion modules 12, 12a, and 12b, compared to another thermoelectric conversion module 12c, the number of the pattern formation steps of the P-type thermoelectric material layer and the N-type thermoelectric material layer can be reduced to half and thus the manufacturing cost can be reduced.

Next, in a case where the thermoelectric conversion layer is formed by a coating composition prepared such a manner that CNT and a surfactant are added to water and dispersed (dissolved), it is preferable to form the thermoelectric conversion layer by forming the thermoelectric conversion layer with the coating composition, then immersing the thermoelectric conversion layer in a solvent for dissolving the surfactant or washing the thermoelectric conversion layer with a solvent for dissolving the surfactant, and drying the thermoelectric conversion layer. Thus, it is possible to form the thermoelectric conversion layer having a very small mass ratio of surfactant/CNT by removing the surfactant from the thermoelectric conversion layer and more preferably not containing the surfactant. The thermoelectric conversion layer is preferably formed as a pattern by printing.

As the printing method, various known printing methods such as screen printing and metal mask printing can be used. In a case where the thermoelectric conversion layer is formed as a pattern by using a coating composition containing CNT, it is more preferable to use metal mask printing. The printing conditions may be appropriately set according to the physical properties (solid content concentration, viscosity, and viscoelastic properties) of the coating composition used, the opening size of a printing plate, the number of openings, the opening shape, a printing area, and the like. Specifically, an attack angle of a squeegee is preferably 50° or less, more preferably 40° or less, and particularly preferably 30° or less. As the squeegee, it is possible to use an obliquely polished squeegee, a sword squeegee, a square squeegee, a flat squeegee, a metal squeegee, and the like. The squeegee direction (printing direction) is preferably the same as the direction in which the thermoelectric conversion elements are connected to each other in series. A clearance is preferably 0.1 to 3.0 mm, and more preferably 0.5 to 2.0 mm. The printing can be performed at a printing pressure of 0.1 to 0.5 MPa in a squeegee indentation amount of 0.1 to 3 mm. By performing printing under such conditions, a CNT-containing thermoelectric conversion layer pattern having a film thickness of 1 μm or more can be suitably formed.

The connection electrodes 34 are formed at both ends of the pattern of the thermoelectric conversion material layer in the temperature difference direction and electrically connect the plurality of thermoelectric conversion material patterns. The connection electrode 34 is not particularly limited as long as the connection electrode 34 is formed of a conductive material, and any material may be used. As the material constituting the connection electrode 34, metal materials such as Al, Cu, Ag, Au, Pt, Cr, Ni, and solder are preferable. From the viewpoint of conductivity or the like, the connection electrode 34 is preferably constituted of copper. In addition, the connection electrode 34 may be constituted of a copper alloy.

The through electrode 28 is formed in the through hole 27 as described above and the inside of the through hole 27 is filled with a conductive material to form the through electrode. The through electrode 28 electrically connects the connection electrodes 34 on both surfaces of the insulating substrate 22.

From the viewpoint of conductivity or the like, the through electrode 28 is preferably constituted of copper. The through electrode 28 is constituted of copper similar to the connection electrode 34, and thus resistance loss or the like can be suppressed. In addition, the through electrode 28 may be constituted of a copper alloy.

The through hole 27 can be formed by numerically controlled (NC) drilling, laser processing, chemical etching, plasma etching or the like. For filling of the inside of the through hole 27 with a conductive material, Cu plating or the like is used.

As described above, the upper electrode 29 electrically connects the P-type thermoelectric conversion elements 24 or the N-type thermoelectric conversion elements 26 in parallel. The upper electrode 29 is not particularly limited as long as the upper electrode is formed of a conductive material, and any material may be used. As the material constituting the upper electrode 29, metal materials such as Al, Cu, Ag, Au, Pt, Cr, Ni, and solder are preferable. The upper electrode 29 is produced at the time of lamination of the thermoelectric conversion module substrate 20. For example, solder paste is applied to the position where the upper electrode 29 is formed and then solder reflow is performed, thereby obtaining the upper electrode 29 from the solder. Therefore, the upper electrode 29 is preferably constituted of solder.

Before the P-type thermoelectric conversion layer 30 and the N-type thermoelectric conversion layer 32 are formed, solder paste is applied to the insulating substrate 22, the P-type thermoelectric conversion layer 30 and the N-type thermoelectric conversion layer 32 are formed, and then solder reflow is performed. Thus, the upper electrode 29 can be formed. In addition to the above methods, the upper electrode 29 can be formed using conductive paste containing a metal powder.

As the connection wirings 42 and 46 used in the thermoelectric conversion module 40, and the connection wirings 56 and 58 used in the thermoelectric conversion module 50, various wirings used for electrically connecting members such as a metal wire such as a copper wire, and a nichrome wire, covered by an insulating layer, can be used.

### Use Form

As to a use form, the thermoelectric conversion device 10 shown in FIG. 1A is used, but there is no limitation thereto.

A thermoelectric conversion module can generate power by bringing an end portion of an insulating substrate in which a thermoelectric conversion element is formed into contact with a frame formed of a known high thermal conductive material such as stainless steel, copper, aluminum, or an aluminum alloy, and bringing the frame into contact with a high temperature portion, thereby forming a heat flow from the end portion in contact with the high temperature portion to the opposite end portion direction. The opposite end portion is also brought into contact with the frame of a known high thermal conductive material such as stainless steel, copper, aluminum, or an aluminum alloy and further a heat dissipating fin is attached to the frame. Thus, a temperature difference between both end portions of the insulating substrate can be increased and the power generation amount can be improved.

At the time of bonding the thermoelectric conversion module to a heat source and generating power, a thermally conductive sheet, a thermally conductive adhesive sheet or a thermally conductive adhesive may be used.

The thermally conductive sheet, the thermally conductive adhesive sheet and the thermally conductive adhesive used by being bonded to a heating side or a cooling side of the thermoelectric conversion module are not particularly limited. Accordingly, commercially available thermally conductive adhesive sheets or thermally conductive adhesives can be used. As the thermally conductive adhesive sheet, for example, it is possible to use TC-50TXS2 manufactured by Shin-Etsu Silicone, a hyper soft heat dissipating material 5580H manufactured by Sumitomo 3M, Ltd., BFG20A manufactured by Denka Company Limited., TR5912F manufactured by NITTO DENKO CORPORATION, and the like. From the viewpoint of heat resistance, a thermally conductive adhesive sheet constituted of a silicone-based pressure sensitive adhesive is preferable. As the thermally conductive adhesive, for example, it is possible to use SCOTCH-WELD EW2070 manufactured by 3M, TA-01 manufactured by Ainex Co., Ltd., TCA-4105, TCA-4210, and HY-910 manufactured by Shiima Electronics, Inc., SST2-RSMZ, SST2-RSCSZ, R3CSZ, and R3MZ manufactured by SATSUMASOKEN CO., LTD., and the like.

The use of the thermally conductive adhesive sheet or the thermally conductive adhesive brings about an effect of increasing a surface temperature of the heating side of the thermoelectric conversion module by improving the adhesiveness with respect to the heat source, an effect of being able to reduce a surface temperature of the cooling side of the thermoelectric conversion module by improving the cooling efficiency, and the like, and accordingly, the power generation amount can be improved.

Further, on the surface of the cooling side of the thermoelectric conversion module, a heat dissipating fin (heat sink) or a heat dissipating sheet consisting of a known material such as stainless steel, copper, aluminum, or an aluminum alloy may be provided. It is preferable to use the heat dissipating fin, since a low temperature side of the thermoelectric conversion module can be more suitably cooled, a large temperature difference is caused between the heat source side and the cooling side, and the thermoelectric conversion efficiency is further improved.

As the heat dissipating fin, it is possible to use various known fins such as T-Wing manufactured by TAIYO WIRE CLOTH CO., LTD, FLEXCOOL manufactured by SHIGYOSOZO KENKYUSHO, a corrugated fin, an offset fin, a waving fin, a slit fin, and a folding fin. Particularly, it is preferable to use a folding fin having a fin height.

The heat dissipating fin preferably has a fin height of 10 to 56 mm, a fin pitch of 2 to 10 mm, and a plate thickness of 0.1 to 0.5 mm. The fin height is more preferably 25 mm or more from the viewpoint that the heat dissipating characteristics are improved, the thermoelectric conversion module can be cooled, and hence the power generation amount is improved. It is preferable to use a heat dissipating fin made of aluminum having a plate thickness of 0.1 to 0.3 mm from the viewpoint of obtaining a fin having high flexibility, lightweight, and the like.

In addition, as the heat dissipating sheet, it is possible to use known heat dissipating sheets such as a PSG graphite sheet manufactured by Panasonic Corporation, COOL STAFF manufactured by Oki Electric Cable Co., Ltd., and CERAC α manufactured by CERAMISSION CO., LTD.

The example in which the thermoelectric conversion module is used in the thermoelectric conversion device using a temperature difference has been described above, but there is no limitation thereto. For example, the thermoelectric conversion module can be used as cooling device which performs cooling by energization.

Hereinafter, the thermoelectric conversion module 12 shown in FIG. 1B having the first thermoelectric conversion module substrate 20, the second thermoelectric conversion module substrate 20, and the third thermoelectric conversion module substrate 20 is exemplified and more specifically described. The first thermoelectric conversion module substrate 20, the second thermoelectric conversion module substrate 20, and the third thermoelectric conversion module substrate 20 have the same structure.

### Preparation of Coating Composition which Becomes P-Type Thermoelectric Conversion Layer

EC (manufactured by Meijo Nano Carbon., average length of CNT: 1 μm or more) as single layer CNT and sodium deoxycholate (manufactured by TOKYO CHEMICAL INDUSTRY CO., LTD.) are added to 20 ml of water such that a mass ratio of CNT/sodium deoxycholate becomes 25/75, thereby preparing a solution.

This solution is mixed for 7 minutes by using a mechanical homogenizer to obtain a premix.

By using a thin film spin system high speed mixer, a dispersion treatment is performed on the obtained premix for 2 minutes at a circumferential speed of 10 msec and then for 5 minutes at a circumferential speed of 40 m/sec in a thermostatic bath with a temperature of 10° C. by a high speed spinning thin film dispersion method, thereby preparing a coating composition which becomes the thermoelectric conversion layer.

The Seebeck coefficient of the P-type thermoelectric conversion material is evaluated using ZEM-3 manufactured by Advance Riko Corporation. As a result, the Seebeck coefficient is 50 μV/K.

### Preparation of Coating Composition which Becomes N-type Thermoelectric Conversion Layer

EC (manufactured by Meijo Nano Carbon., average length of CNT: 1 μm or more) as single layer CNT and EMULGEN 350 (manufactured by Kao Corporation) are added to 20 ml of water such that a mass ratio of CNT/EMULGEN 250 becomes 25/75, thereby preparing a solution.

This solution is mixed for 7 minutes by using a mechanical homogenizer to obtain a premix.

By using a thin film spin system high speed mixer, a dispersion treatment is performed on the obtained premix for 2 minutes at a circumferential speed of 10 msec and then for 5 minutes at a circumferential speed of 40 m/sec in a thermostatic bath with a temperature of 10° C. by a high speed spinning thin film dispersion method, thereby preparing a coating composition which becomes the thermoelectric conversion layer.

The Seebeck coefficient of the N-type thermoelectric conversion material is evaluated using ZEM-3 manufactured by Advance Riko Corporation. As a result, the Seebeck coefficient is −30 μV/K.

### Insulating Substrate

The copper substrate 50 (refer to FIG. 4C) in which the copper layers 52 (refer to FIG. 4C) having a thickness of 12 μm are formed on both surfaces of a polyimide substrate having a thickness of 12.5 μm is prepared. The polyimide substrate is the insulating substrate 22 (refer to FIG. 4C).

Next, one copper layer 52 (refer to FIG. 4C) of the copper substrate 50 is etched by a photolithography method to form the hole 54 (refer to FIG. 4F) at the position of the through hole formation portion. Next, the polyimide substrate is etched to form the through hole 27 (refer to FIG. 4I). Next, through-hole plating of copper is performed on the through hole to form the through electrode 28 (refer to FIG. 4L). The through-hole plating is performed by electroless plating and electrolytic plating.

Next, one copper layer 52 (refer to FIG. 4J) is etched by a photolithography method to form the connection electrodes 34 (refer to FIG. 4M) as patterns. Then, the other copper layer 52 (refer to FIG. 4N) is etched by a photolithography method to form the connection electrodes 34 (refer to FIG. 4Q) as patterns.

### Production of First Thermoelectric Conversion Module Substrate

The P-type thermoelectric conversion layer 30 (refer to FIG. 5D) is formed on one surface of the insulating substrate 22 (refer to FIG. 5A) by metal mask printing.

The patterns of the coating composition are formed by metal mask printing by setting a squeegee direction to be the direction in which the thermoelectric conversion elements are connected to each other in series, under the conditions of an attack angle of 20°, a clearance of 1.5 mm, a printing pressure of 0.3 MPa, and an indentation amount of 0.1 mm., and dried for 5 minutes at 50° C. and then for 5 minutes at 120° C.

Next, the N-type thermoelectric conversion layer 32 (refer to FIG. 5H) is formed on the other surface of the insulating substrate 22 (refer to FIG. 5E) by metal mask printing. The printing conditions are the same as the printing conditions in the formation of the P-type thermoelectric conversion layer.

Next, the resultant is immersed in ethanol for 1 hour to remove sodium deoxycholate from the P-type thermoelectric conversion layer and the N-type thermoelectric conversion layer, and dried for 10 minutes at 50° C. and then for 120 minutes at 120° C. The film thickness of each of the P-type thermoelectric conversion layer and the N-type thermoelectric conversion layer after drying is 10 μm.

Next, cream solder is formed by metal mask printing so as to cover the connection portions 35 of the connection electrodes and the thermoelectric conversion material layer on both surfaces of the insulating substrate (refer to FIGS. 5J and 5K). In this manner, the first thermoelectric conversion module substrate 20 (refer to FIG. 5L) can be produced.

In the same manner as in the preparation of the first thermoelectric conversion module substrate, the second thermoelectric conversion module substrate and the third thermoelectric conversion module substrate are produced.

### Lamination of Thermoelectric Conversion Module Substrates

As shown in FIG. 1A, the first thermoelectric conversion module substrate 20, the second thermoelectric conversion module substrate 20, and the third thermoelectric conversion module substrate 20 are overlapped by aligning the positions of the upper and lower connection electrodes 34 of the P-type thermoelectric conversion elements 24 and the N-type thermoelectric conversion elements 26 such that the N-type thermoelectric conversion layer 32 of the first thermoelectric conversion module substrate 20, and the N-type thermoelectric conversion layer 32 of the second thermoelectric conversion module substrate 20, and the P-type thermoelectric conversion layer 30 of the second thermoelectric conversion module substrate 20, and the P-type thermoelectric conversion layer 30 of the third thermoelectric conversion module substrate 20 are arranged to face each other.

After the substrates are overlapped, the first thermoelectric conversion module substrate 20 to the third thermoelectric conversion module substrate 20 are fixed by the frame 16 made of aluminum subjected to an alumite treatment from the outer sides of the first thermoelectric conversion module substrate 20 and the third thermoelectric conversion module substrate 20, and solder reflow is performed for 1 minute at 220° C. three times. Then, the N-type thermoelectric conversion element 26 of the first thermoelectric conversion module substrate 20, the N-type thermoelectric conversion element 26 of the second thermoelectric conversion module substrate 20, the P-type thermoelectric conversion element 24 of the second thermoelectric conversion module substrate 20, and the P-type thermoelectric conversion element 24 of the third thermoelectric conversion module substrate 20 are electrically connected to each other in parallel.

Thus, the thermoelectric conversion module 12 in which the first thermoelectric conversion module substrate 20 to the third thermoelectric conversion module substrate 20 are overlapped is produced.

A temperature difference of 20° C. was made between the connection electrode 34 side in one end portion of the thermoelectric conversion module 12 and the connection electrode 34 side in the other end thereof and a lead wire was drawn from the connection electrode 34 of the first thermoelectric conversion module substrate 20 and from the connection electrode 34 of the third thermoelectric conversion module substrate 20 and connected to a source meter 6430 manufactured by KEITHLEY, Co., Ltd. to evaluate power generation properties. An open voltage of 3.2 mV of the thermoelectric conversion module 12 was obtained. In the thermoelectric conversion module 12, from a Seebeck coefficient of 50 μV/K of the P-type thermoelectric conversion layer and a Seebeck coefficient of −30 μV/K of the N-type thermoelectric conversion layer, the open voltage as designed was confirmed.

Accordingly according to the present invention, in the thermoelectric conversion module in which the thermoelectric conversion elements were formed on both surfaces of the insulating substrate and the plurality of thermoelectric conversion module substrates were overlapped, it was possible to prevent a decrease in the power generation amount by an unnecessary short circuit of the thermoelectric conversion element between the facing insulating substrates, and thus high integration could be achieved.

The present invention is basically constituted as described above. While the thermoelectric conversion module of the present invention has been described above in detail, the present invention is not limited to the above embodiments, and various improvements and modifications may of course be made without departing from the spirit of the present invention.

### EXPLANATION OF REFERENCES

10: thermoelectric conversion device
12, 12a, 12b, 40, 50: thermoelectric conversion module
12c: another thermoelectric conversion module
14: base
16: frame
20, 60: thermoelectric conversion module substrate
22: insulating substrate
22a: first insulating substrate
22b: second insulating substrate
24: P-type thermoelectric conversion element
26: N-type thermoelectric conversion element
28: through electrode
29: upper electrode
30: P-type thermoelectric conversion layer
32: N-type thermoelectric conversion layer
34: connection electrode
35: connection portion
42, 46, 56, 58: connection wiring
52: P-type thermoelectric conversion module substrate
54: N-type thermoelectric conversion module substrate
52A: P-type laminate
54A: N-type laminate

What is claimed is:

1. A thermoelectric conversion module comprising:
a thermoelectric conversion module substrate in which a P-type thermoelectric conversion element having a P-type thermoelectric conversion layer and a pair of connection electrodes, which are electrically connected to the P-type thermoelectric conversion layer, is provided on at least one surface of an insulating substrate, and an N-type thermoelectric conversion element having an N-type thermoelectric conversion layer and a pair of connection electrodes, which are electrically connected to the N-type thermoelectric conversion layer, is provided on at least the other surface of the insulating substrate,
wherein the connection electrodes formed on the one surface of the insulating substrate and the connection electrodes formed on the other surface of the insulating substrate opposite to the one surface are electrically connected to each other, and
a plurality of the thermoelectric conversion module substrates are laminated such that the P-type thermoelectric conversion elements or the N-type thermoelectric conversion elements are made to face each other, and the respective laminated thermoelectric conversion module substrates is connected to each other through the connection electrodes.

2. The thermoelectric conversion module according to claim 1,
wherein the connection electrode formed on the one surface of the insulating substrate and the connection electrode formed on the other surface of the insulating substrate opposite to the one surface are electrically connected to each other by at least one through electrode formed on the insulating substrate.

3. The thermoelectric conversion module according to claim 1,
wherein the P-type thermoelectric conversion elements or the N-type thermoelectric conversion elements in the respective laminated thermoelectric conversion module substrates are electrically connected to each other in parallel through the connection electrodes.

4. The thermoelectric conversion module according to claim 1,
wherein the P-type thermoelectric conversion element and the N-type thermoelectric conversion element in the respective laminated thermoelectric conversion module substrates are electrically connected to each other through the connection electrodes.

5. The thermoelectric conversion module according to claim 1,
wherein only the P-type thermoelectric conversion element is provided on one surface of the insulating substrate and only the N-type thermoelectric conversion element is provided on the other surface of the insulating substrate.

6. The thermoelectric conversion module according to claim 1,
wherein the P-type thermoelectric conversion element and the N-type thermoelectric conversion element are electrically connected to each other in series on one surface of the insulating substrate, and the P-type thermoelectric conversion element and the N-type thermoelectric conversion element are electrically connected to each other in series on the other surface of the insulating substrate.

7. The thermoelectric conversion module according to claim 1,
wherein the P-type thermoelectric conversion elements or the N-type thermoelectric conversion elements in the respective laminated thermoelectric conversion module substrates are electrically connected to each other in parallel by upper electrodes provided on at least the connection electrodes.

8. The thermoelectric conversion module according to claim 7,
wherein the upper electrodes are provided so as to cover connection portions of the connection electrodes and the P-type thermoelectric conversion layer and connection portions of the connection electrodes and the N-type thermoelectric conversion layer.

9. The thermoelectric conversion module according to claim 7,
wherein the upper electrodes are separately provided on one connection electrode side of the pair of connection electrodes and on the other connection electrode side.

10. The thermoelectric conversion module according to claim 1,
wherein the insulating substrate is formed of a polyimide.

11. The thermoelectric conversion module according to claim 1,
wherein the connection electrode is formed of copper.

12. The thermoelectric conversion module according to claim 2,
wherein the through electrode is formed of copper.

13. The thermoelectric conversion module according to claim 1,
wherein the P-type thermoelectric conversion layer and the N-type thermoelectric conversion layer are formed of an organic thermoelectric conversion material.

14. The thermoelectric conversion module according to claim 1,
wherein the P-type thermoelectric conversion layer and the N-type thermoelectric conversion layer contain a carbon nanotube.

15. The thermoelectric conversion module according to claim 7,
wherein the upper electrode is formed of solder.

16. A thermoelectric conversion module comprising:
a P-type thermoelectric conversion module substrate in which a P-type thermoelectric conversion element having a P-type thermoelectric conversion layer and a pair of connection electrodes, which are electrically connected to the P-type thermoelectric conversion layer, is provided on one surface of an insulating substrate; and
an N-type thermoelectric conversion module substrate in which an N-type thermoelectric conversion element having an N-type thermoelectric conversion layer and a pair of connection electrodes, which are electrically connected to the N-type thermoelectric conversion layer, is provided on one surface of the insulating substrate,
wherein a P-type laminate formed by laminating two sheets of the P-type thermoelectric conversion module substrate such that the P-type thermoelectric conversion elements are arranged to face each other and an N-type laminate formed by laminating two sheets of the N-type thermoelectric conversion module substrate such that the N-type thermoelectric conversion elements are arranged to face each other are alternately laminated and in the laminated P-type laminate and N-type laminate, the P-type thermoelectric conversion element of the P-type thermoelectric conversion module substrate and the N-type thermoelectric conversion element of the N-type thermoelectric conversion module substrate are electrically connected to each other through the connection electrodes.
